(19) United States
(12) Patent Application Publication
(10) Pub. No.: US 2025/0329499 A1
(43) Pub. Date: Oct. 23, 2025

(54) THIN FILM CAPACITOR AND ELECTRONIC CIRCUIT HAVING THE SAME

(71) Applicant: TDK Corporation, Tokyo (JP)

(72) Inventors: Masahiro HIRAOKA, Tokyo (JP); Hitoshi SAITA, Tokyo (JP)

(21) Appl. No.: 18/870,890

(22) PCT Filed: May 11, 2023
(86) PCT No.: PCT/JP2023/017716

§ 371 Date: Dec. 2, 2024

Related U.S. Application Data
(60) Provisional application No. 63/355,800, filed on Jun. 27, 2022.

(51) Int. Cl. H01G 4/33; H01G 2/10; H01G 4/008

(52) U.S. Cl. CPC H01G 4/33; H01G 2/10; H01G 4/008

(57) ABSTRACT

To provide a thin film capacitor with excellent heat dissipation performance. A thin film capacitor includes: a lower electrode layer made of a metal foil; an upper electrode layer covering a surface of the lower electrode layer through a dielectric layer; a passivation layer covering the surface of the lower electrode layer so as to embed therein the dielectric layer and upper electrode layer; terminal electrodes provided on the passivation layer; a via conductor penetrating the passivation layer and connecting the terminal electrode and lower electrode layer; and a via conductor penetrating the passivation layer and connecting the terminal electrode and upper electrode layer. The terminal electrode has a planer size larger than that of the terminal electrode, and the via conductor has a sectional area larger than that of the via conductor.

### TECHNICAL FIELD

The present disclosure relates to a thin film capacitor and an electronic circuit having the same and, more particularly, to a thin film capacitor with excellent heat dissipation performance and an electronic circuit having such a thin film capacitor.

### BACKGROUND ART

Patent Document 1 discloses a thin film capacitor having an insulting protective film covering lower and upper electrodes and a pair of terminal electrodes provided of the insulating protective film and on the surface connected respectively to the lower and upper electrodes through their corresponding via conductors.

### CITATION LIST

### Patent Document

[Patent Document 1] JP 2018-011028A.

### DISCLOSURE OF THE INVENTION

### Problem to be Solved by the Invention

However, the thin film capacitor described in Patent Document 1 has insufficient heat dissipation performance.

The present disclosure describes a thin film capacitor with excellent heat dissipation performance and an electronic circuit having such a thin film capacitor.

### Means for Solving the Problem

A thin film capacitor according to an aspect of the present disclosure includes: a lower electrode layer made of a metal foil; an upper electrode layer covering one surface of the lower electrode layer through a dielectric layer; a passivation layer covering the one surface of the lower electrode layer so as to embed therein the dielectric layer and upper electrode layer; first and second terminal electrodes provided on the passivation layer; a first via conductor penetrating the passivation layer and connecting the first terminal electrode and the lower electrode layer; and a second via conductor penetrating the passivation layer and connecting the second terminal electrode and the upper electrode layer. The first terminal electrode has a planer size larger than that of the second terminal electrode, and the first via conductor has a sectional area larger than that of the second via conductor. This enhances heat dissipation performance through the lower electrode layer.

An electronic circuit according to an aspect of the present disclosure includes a switching element and the above thin film capacitors connected in parallel to the switching element.

### Advantageous Effects of the Invention

According to the present disclosure, a thin film capacitor with excellent heat dissipation performance and an electronic circuit having such a thin film capacitor are provided.

### BRIEF DESCRIPTION OF THE DRAWINGS

FIG. 1A is a schematic plan view of a thin film capacitor 10 according to an embodiment of the technology according to the present disclosure. FIG. 1B is a schematic cross-sectional view taken along the line A-A in FIG. 1A.

FIG. 2 is a circuit diagram of an electronic circuit 40 using the thin film capacitor 10.

FIG. 3 is a diagram for explaining the effect of the thin film capacitor 10 in the electronic circuit 40.

FIG. 4 is a schematic diagram showing an example in which the thin film capacitor 10 and the switching element 43 are mounted on the surface of a circuit board 50.

FIG. 5 is a schematic diagram showing an example in which the thin film capacitor 10 is packaged in a package 60 of a switching element 43.

FIG. 6 is a schematic diagram showing an example in which the thin film capacitor 10 is embedded in a circuit board 70 on which a switching element 43 is mounted.

FIG. 7A is a schematic plan view of a thin film capacitor 10A according to a first modification. FIG. 7B is a schematic cross-sectional view taken along the line A-A in FIG. 7A.

FIG. 8 is a schematic cross-sectional view of a thin film capacitor 10B according to a second modification.

FIG. 9 is a schematic cross-sectional view of a thin film capacitor 10C according to a third modification.

FIG. 10 is a schematic cross-sectional view of a thin film capacitor 10D according to a fourth modification.

### MODE FOR CARRYING OUT THE INVENTION

Hereinafter, preferred embodiments of the present invention will be described in detail with reference to the accompanying drawings.

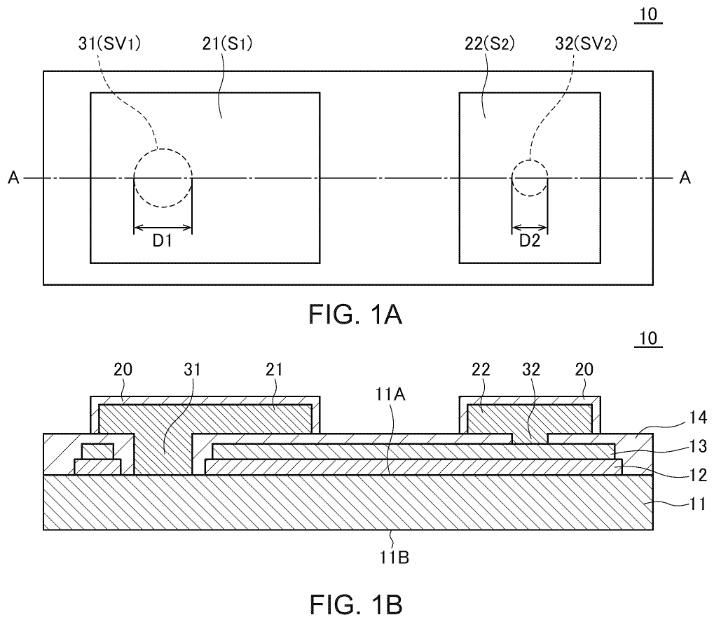

FIG. 1A is a schematic plan view of a thin film capacitor 10 according to an embodiment of the technology according to the present disclosure. FIG. 1B is a schematic cross-sectional view taken along the line A-A in FIG. 1A.

As illustrated in FIGS. 1A and 1B, the thin film capacitor 10 according to the present embodiment has a lower electrode layer 11 made of a metal foil, an upper electrode layer 13 covering one surface 11A of the lower electrode layer 11 through a dielectric layer 12, a passivation layer 14 covering the surface 11A of the lower electrode layer 11 so as to embed therein the dielectric layer 12 and upper electrode layer 13, and terminal electrodes 21 and 22 provided on the passivation layer 14.

The lower electrode layer 11 is a metal foil made of a high-melting-point metal such as nickel (Ni) and also functions as a support for ensuring mechanical strength of the thin film capacitor 10. In the example illustrated in FIG. 1B, the other surface 11B of the lower electrode layer 11 is exposed.

The dielectric layer 12 is made of a perovskite dielectric material. Examples of the perovskite dielectric material include a ferroelectric material or a paraelectric material having a perovskite structure, such as BaTiO₃ (barium titanate), (Ba₁₋ₓSrₓ)TiO₃ (barium strontium titanate), (Ba₁₋ₓCax)TiO₃, PbTiO₃, Pb(ZrₓTi₁₋ₓ)O₃, (Sr₁₋ₓCaₓ), (Ti_{1-y}Zr_{y}), Ba(Mg_{1/3}Ta_{2/3}), a composite perovskite relaxer type ferroelectric material represented by Pb (Mg_{1/3}Nb_{2/3})O₃, and the like, a bismuth layer compound represented by Bi₄Ti₃O₁₂, a tungsten bronze type ferroelectric material represented by (Sr₁₋ₓBaₓ)Nb₂O₆ and PbNb₂O₆. Here, in the above-described perovskite structure, perovskite relaxer type ferroelectric material, bismuth layer compound, and tungsten bronze type ferroelectric material, the ratio of A site and B site is usually an integer ratio but may be purposefully shifted from the integer ratio in order to improve characteristics. In order to control the characteristics of the dielectric layer 12, the dielectric layer 12 may appropriately contain an additive substance as a subcomponent. The relative permittivity (εᵣ) is 10 or more, for example. The larger the relative permittivity of the dielectric layer 12, the better, and there is not particular restriction on the upper limit value thereof. Further, the larger the dielectric withstand voltage of the dielectric layer 12, the better, and there is not particular restriction on the upper limit value thereof. The thickness of the dielectric layer 12 is about 10 nm to about 6000 nm, for example.

The upper electrode layer 13 is made of copper (Cu), for example. The thickness of the upper electrode layer 13 is smaller than the thickness of the lower electrode layer 11 functioning as a support. The passivation layer 14 is made of an insulating material such as resin and provided on the surface 11A of the lower electrode layer 11 so as to embed therein the dielectric layer 12 and upper electrode layer 13. The terminal electrodes 21 and 22 provided on the surface of the passivation layer 14 are connected respectively to the lower electrode layer 11 and the upper electrode layer 13 through their corresponding via conductors 31 and 32 penetrating the passivation layer 14. The terminal electrodes 21, 22 and via conductors 31, 32 are made of copper (Cu), for example. The terminal electrode (21, 22) and via conductor (31, 32) may be integrally formed with each other.

In the thin film capacitor 10 according to the present embodiment, when the planar size of the terminal electrode 21 and that of the terminal electrode 22 are assume to be S₁ and S₂, respectively, S₁>S₂ is satisfied. Further, when the sectional area of the via conductor 31 and that of the via conductor 32 are assumed to be SV₁ and SV₂, respectively, SV₁>SV₂ is satisfied. The planar size of each of the terminal electrodes 21 and 22 is the size thereof as viewed in the stacking direction. The sectional area of each of the via conductors 31 and 32 is the sectional size thereof as viewed in a direction perpendicular to the stacking direction. In the example illustrated in FIG. 1A, the via conductors 31 and 32 both have a circular planar shape. Therefore, a diameter D1 of the via conductor 31 is larger than a diameter D2 of the via conductor 32.

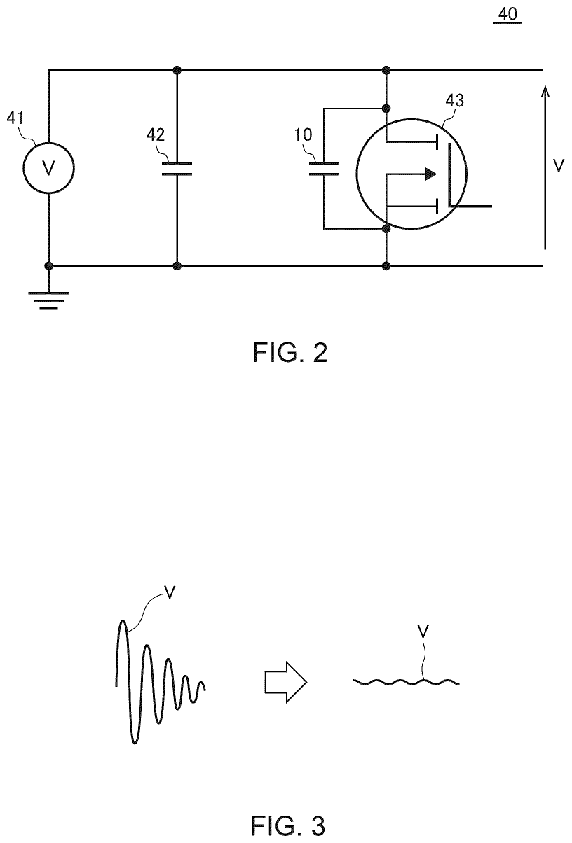

As illustrated in FIG. 2, the thin film capacitor 10 according to the present embodiment can be used as a snubber capacitor. An electronic circuit 40 illustrated in FIG. 2 is a part of a DC-DC converter circuit, a part of an AC-DC converter circuit, or a part of an inverter circuit and includes a DC power supply 41, an input capacitor 42, and a switching element 43 such as an FET. The switching element 43 may be a power device using a semiconductor material such as Si, Sic, or GaN. When the switching speed of the switching element 43 is high, a voltage fluctuates due to a parasitic inductance component. Such a voltage fluctuation is reduced when the snubber capacitor is connected to the vicinity of the switching element 43. Thus, connecting the thin film capacitor 10 in parallel to the switching element 43 can suppress the fluctuation of an output voltage V immediately after switching operation, as illustrated in FIG. 3.

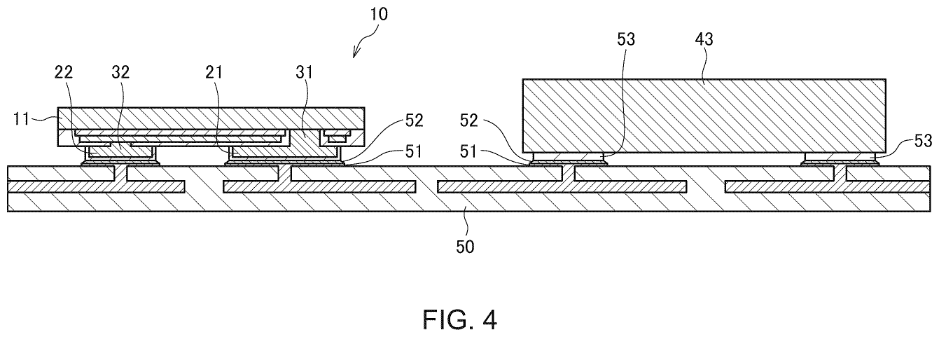

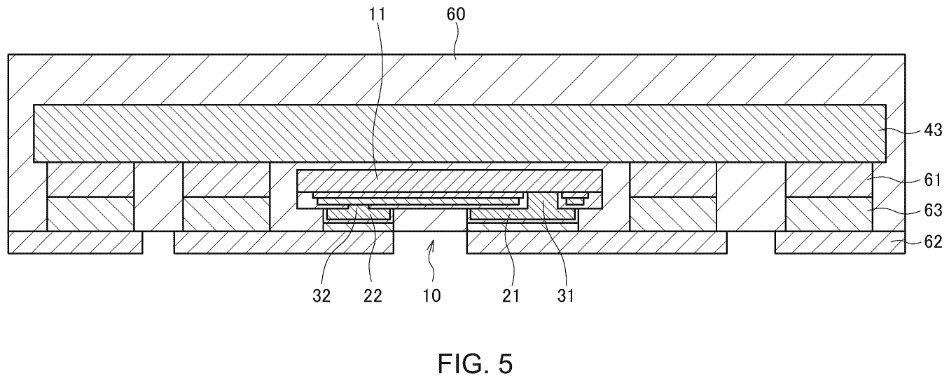

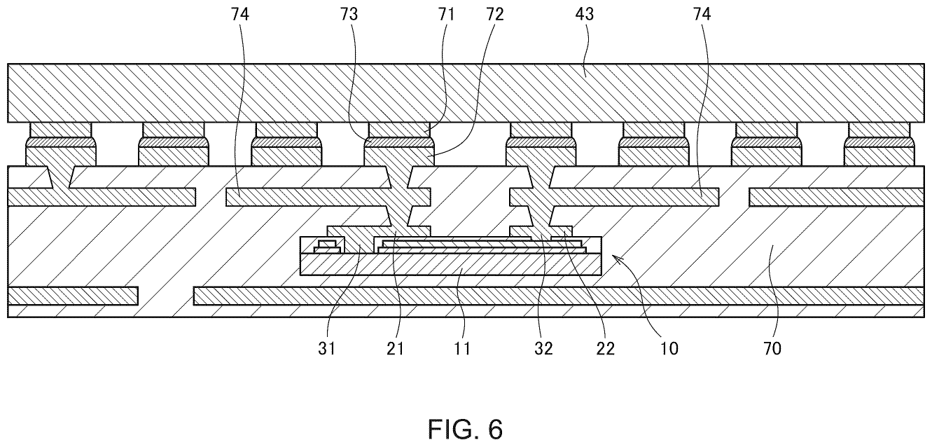

The thin film capacitor 10 according to the present embodiment may be mounted on the surface of a circuit board 50 together with switching element 43 as illustrated in FIG. 4, may be packaged in a package 60 of the switching element 43 as illustrated in FIG. 5, or may be embedded in a circuit board 70 on which the switching element 43 is mounted as illustrated in FIG. 6.

In the example illustrated in FIG. 4, the switching element 43 and thin film capacitor 10 are mounted on the surface of the circuit board 50. A plurality of land patterns 51 are provided on the surface of the circuit board 50, and given land patterns 51 are respectively connected to the terminal electrodes 21 and 22 of the thin film capacitor 10 through a solder 52, and another land pattern 51 is connected to the terminal electrode 53 of the switching element 43 through the solder 52. The switching element 43 generates heat through switching operation. The heat generated from the switching element 43 is dissipated through the circuit board 50 and to its surrounding space. This may result in an increase in the temperature of the surrounding space; however, in the example of FIG. 4, the thin film capacitor 10 is provided adjacent to the switching element 43, and therefore, the heat of the surrounding space is transmitted to the circuit board 50 through the thin film capacitor 10. The heat transmitted from the surrounding space to the lower electrode layer 11 at this time is mainly transmitted to the circuit board 50 through the via conductor 31 and terminal electrode 21. In the present embodiment, the sectional area of the via conductor 31 is larger than that of the via conductor 32, and the planar size of the terminal electrode 21 is larger than that of the terminal electrode 22, so that the heat transmitted from the surrounding space to the lower electrode layer 11 is efficiently transmitted to the circuit board 50.

In the example illustrated in FIG. 5, the switching element 43 is packaged in the package 60. In the package 60, a terminal electrode 61 of the switching element 43 and a lead frame 62 constituting an external terminal of the package 60 are connected to each other through a solder 63. Further, in the example of FIG. 5, the thin film capacitor 10 is packaged in the package 60 together with the switching element 43. The terminal electrodes 21 and 22 of the thin film capacitor 10 are connected to the lead frame 62 through the solder 63. Thus, the heat generated from the switching element 43 is transmitted to the lead frame 62 not only through the terminal electrode 61 but also through the thin film capacitor 10. The heat transmitted from the inside of the package 60 to the lower electrode layer 11 is mainly transmitted to the circuit board 50 through the via conductor 31 and terminal electrode 21. In the present embodiment, the sectional area of the via conductor 31 is larger than that of the via conductor 32, and the planar size of the terminal electrode 21 is larger than that of the terminal electrode 22, so that the heat in the package 60 is efficiently transmitted to the lead frame 62.

In the example illustrated in FIG. 6, the switching element 43 is mounted on the surface of the circuit board 70. A terminal electrode 71 of the switching element 43 and a land pattern 72 of the circuit board 70 are connected to each other through a solder 73. Further, in the example of FIG. 6, the thin film capacitor 10 is embedded inside the circuit board 70. The terminal electrodes 21 and 22 of the thin film capacitor 10 are connected to a conductor pattern 74 positioned in the inner layer of the circuit board 70. Thus, the heat generated from the switching element 43 is transmitted to the circuit board 70 through the terminal electrode 71, and a part of the heat transmitted to the circuit board 70 is dissipated through the thin film capacitor 10. In the present embodiment, the planar size of the terminal electrode 21 is larger than that of the terminal electrode 22, and the sectional area of the via conductor 31 is larger than that of the via conductor 32, enhancing heat conductivity of the circuit board 70.

As described above, in the thin film capacitor 10 according to the present embodiment, the planar size Si of the terminal electrode 21 is larger than the planar size S₂ of the terminal electrode 22 (S₁>S₂), and the sectional area SV₁ of the via conductor 31 is larger than the sectional area SV₂ of the via conductor 32 (SV₁>SV₂), thereby enhancing heat dissipation performance through the lower electrode layer 11 functioning as a support. Thus, when the thin film capacitor 10 according to the present embodiment is used as a snubber capacitor that is connected to the switching element 43 large in heat generation, heat generated from the switching element 43 can be dissipated outside efficiently.

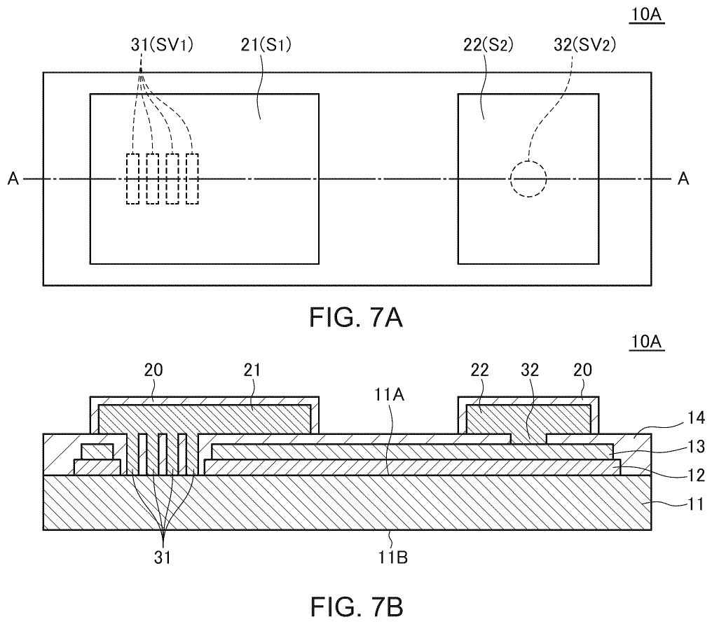

FIG. 7A is a schematic plan view of a thin film capacitor 10A according to a first modification. FIG. 7B is a schematic cross-sectional view taken along the line A-A in FIG. 7A.

As illustrated in FIGS. 7A and 7B, the thin film capacitor 10A according to the first modification differs from the thin film capacitor 10 illustrated in FIGS. 1A and 1B in that it has a plurality of the via conductors 31. Other basic configurations are the same as those of the thin film capacitor 10, so the same reference numerals are given to the same elements, and overlapping description will be omitted. As represented in the thin film capacitor 10A according to the first modification, the via conductor 31 may be divided into a plurality of pieces. In this case, the sum of the sectional areas of the plurality of via conductors 31 is larger than the sectional area of the via conductor 32. The sectional area of each of the via conductors 31 may be smaller than the sectional area of the via conductor 32. Further, as illustrated in FIG. 7A, the via conductors 31 may have a rectangular planar shape. As described above, dividing the via conductor 31 into a plurality of pieces enhances design freedom.

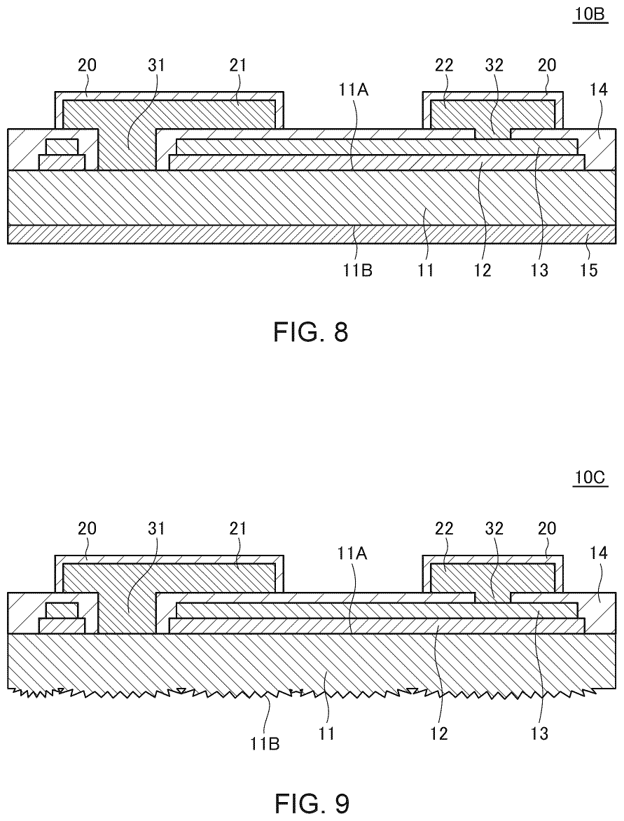

FIG. 8 is a schematic cross-sectional view of a thin film capacitor 10B according to a second modification.

As illustrated in FIG. 8, the thin film capacitor 10B according to the second modification differs from the thin film capacitor 10 illustrated in FIGS. 1A and 1B in that the surface 11B of the lower electrode layer 11 is covered with a metal layer 15. Other basic configurations are the same as those of the thin film capacitor 10, so the same reference numerals are given to the same elements, and overlapping description will be omitted. The metal layer is made of a material, such as Cu, NiPdAu, or AuSn, different from the metal foil constituting the lower electrode layer 11. As represented in the thin film capacitor 10B according to the second modification, the surface 11B of the lower electrode layer 11 need not be exposed but may be covered with the metal layer 15 made of a material different from the metal foil constituting the lower electrode layer 11. For example, covering the surface 11B of the lower electrode layer 11 with the metal layer 15 made of Cu further enhances heat conductivity. Further, covering the surface 11B of the lower electrode layer 11 with the metal layer 15 made of NiPdAu or AuSn enhances solder wettability.

FIG. 9 is a schematic cross-sectional view of a thin film capacitor 10C according to a third modification.

As illustrated in FIG. 9, the thin film capacitor 10C according to the third modification differs from the thin film capacitor 10 illustrated in FIGS. 1A and 1B in that the surface 11B of the lower electrode layer 11 is roughened to make the surface roughness of the surface 11B higher than that of the surface 11A. Other basic configurations are the same as those of the thin film capacitor 10, so the same reference numerals are given to the same elements, and overlapping description will be omitted. As represented in the thin film capacitor 10C according to the third modification, roughening the surface 11B of the lower electrode layer 11 enhances heat dissipation through the lower electrode layer 11 and adhesion between the surface 11B of the lower electrode layer 11 and another member.

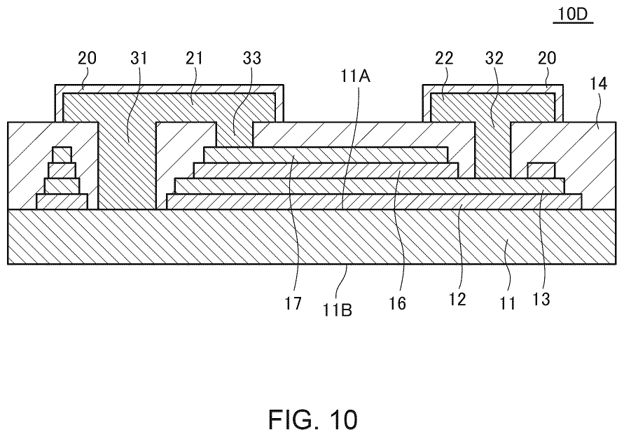

FIG. 10 is a schematic cross-sectional view of a thin film capacitor 10D according to a fourth modification.

As illustrated in FIG. 10, the thin film capacitor 10D according to the fourth modification differs from the thin film capacitor 10 illustrated in FIGS. 1A and 1B in that it additionally has another dielectric layer 16 covering the upper electrode layer 13 and another lower electrode layer 17 covering the upper electrode layer 13 through the dielectric layer 16. The lower electrode layer 17 is connected to the terminal electrode 21 through a via conductor 33 penetrating the passivation layer 14. Other basic configurations are the same as those of the thin film capacitor 10, so the same reference numerals are given to the same elements, and overlapping description will be omitted. As represented in the thin film capacitor 10D according to the fourth modification, disposing the lower electrode layers 17 and 11 above and below the upper electrode layer 13 through the respective dielectric layers 16 and 12 allows larger capacitance to be achieved. In this case, by making the sectional area of the via conductor 31 connected to the lower electrode layer 11 larger than the sectional area of the via conductor 33 connected to the lower electrode layer 17, higher heat dissipation performance can be achieved.

While the preferred embodiment of the present disclosure has been described, the present disclosure is not limited to the above embodiment, and various modifications may be made within the scope of the present disclosure, and all such modifications are included in the present disclosure.

The technology according to the present disclosure includes the following configuration examples but not limited thereto.

A thin film capacitor according to an aspect of the present disclosure includes: a lower electrode layer made of a metal foil; an upper electrode layer covering one surface of the lower electrode layer through a dielectric layer; a passivation layer covering the one surface of the lower electrode layer so as to embed therein the dielectric layer and upper electrode layer; first and second terminal electrodes provided on the passivation layer; a first via conductor penetrating the passivation layer and connecting the first terminal electrode and the lower electrode layer; and a second via conductor penetrating the passivation layer and connecting the second terminal electrode and the upper electrode layer. The first terminal electrode has a planer size larger than that of the second terminal electrode, and the first via conductor has a sectional area larger than that of the second via conductor. This enhances heat dissipation performance through the lower electrode layer.

The above thin film capacitor may have a plurality of the first via conductors, and the sum of the sectional areas of the plurality of first via conductors may be larger than the sectional area of the second via conductor. This enhances design freedom.

The above thin film capacitor may further include a metal layer covering the other surface of the lower electrode layer and made of a material different from the metal foil. This further enhances heat dissipation performance through the lower electrode layer.

In the above thin film capacitor, the other surface of the lower electrode layer may be higher in surface roughness than the one surface of the lower electrode layer. This further enhances heat dissipation performance through the lower electrode layer.

The above thin film capacitor may further include another lower electrode layer covering the upper electrode layer through another dielectric layer and a third via conductor penetrating the passivation layer and connecting the first terminal electrode and the another lower electrode layer, and the first via conductor may have a sectional area larger than that of the third via conductor. This allows larger capacitance to be achieved.

An electronic circuit according to an aspect of the present disclosure includes a switching element and any one of the above thin film capacitors connected in parallel to the switching element. This allows the thin film capacitor to function as a snubber capacitor and to efficiently dissipate heat generated from the switching element.

In the above electronic circuit, the switching element and the thin film capacitor may be mounted on the surface of the same circuit board or may be packaged in the same package. Alternatively, the thin film capacitor may be embedded in a circuit board on which the switching element is mounted. By thus disposing the switching element and thin film capacitor in proximity to each other, heat generated from the switching element can be dissipated efficiently.

### Reference Signs List

10, 10A-10D thin film capacitor
11 lower electrode layer
11A one surface of lower electrode layer
11B other surface of lower electrode layer
12 dielectric layer
13 upper electrode layer
14 passivation layer
15 metal layer
16 dielectric layer
17 lower electrode layer
21, 22 terminal electrode
31-33 via conductor
40 electronic circuit
41 DC power supply
42 input capacitor
43 switching element
50 circuit board
51 land pattern
52 solder
53 terminal electrode
60 package
61 terminal electrode
62 lead frame
63 solder
70 circuit board
71 terminal electrode
72 land pattern
73 solder
74 conductor pattern

1. A thin film capacitor comprising:
a lower electrode layer made of a metal foil;
an upper electrode layer covering one surface of the lower electrode layer through a dielectric layer;
a passivation layer covering the one surface of the lower electrode layer so as to embed therein the dielectric layer and upper electrode layer;
first and second terminal electrodes provided on the passivation layer;
a first via conductor penetrating the passivation layer and connecting the first terminal electrode and the lower electrode layer; and
a second via conductor penetrating the passivation layer and connecting the second terminal electrode and the upper electrode layer,
wherein the first terminal electrode has a planer size larger than that of the second terminal electrode, and
wherein the first via conductor has a sectional area larger than that of the second via conductor.

2. The thin film capacitor as claimed in claim 1,
wherein a plurality of the first via conductors are provided, and
wherein a sum of sectional areas of the plurality of first via conductors is larger than a sectional area of the second via conductor.

3. The thin film capacitor as claimed in claim 1, further comprising a metal layer covering other surface of the lower electrode layer and made of a material different from the metal foil.

4. The thin film capacitor as claimed in claim 1, wherein other surface of the lower electrode layer is higher in surface roughness than the one surface of the lower electrode layer.

5. The thin film capacitor as claimed in claim 1, further comprising:
another lower electrode layer covering the upper electrode layer through another dielectric layer; and
a third via conductor penetrating the passivation layer and connecting the first terminal electrode and the another lower electrode layer,
wherein the first via conductor has a sectional area larger than that of the third via conductor.

6. An electronic circuit comprising:
a switching element; and
the thin film capacitor as claimed in claim 1 connected in parallel to the switching element.

7. The electronic circuit as claimed in claim 6, wherein the switching element and the thin film capacitor are mounted on a surface of a same circuit board.

8. The electronic circuit as claimed in claim 6, wherein the switching element and the thin film capacitor are packaged in a same package.

9. The electronic circuit as claimed in claim 6, wherein the thin film capacitor is embedded in a circuit board on which the switching element is mounted.
